(19) United States
(12) Patent Application Publication
(10) Pub. No.: US 2026/0025988 A1
(43) Pub. Date: Jan. 22, 2026

(54) MEMORY DEVICE INCLUDING BOTTOM ELECTRODE AND METHOD OF FORMING THE SAME

(71) Applicant: SK hynix Inc., Gyeonggi-do (KR)

(72) Inventor: Heon Yong CHANG, Gyeonggi-do (KR)

(21) Appl. No.: 18/948,478

(22) Filed: Nov. 15, 2024

(30) Foreign Application Priority Data
Jul. 18, 2024 (KR) 10-2024-0094727

(51) Int. Cl. H10B 12/00

(52) U.S. Cl. CPC H10B 12/50; H10B 12/09; H10B 12/315

(57) ABSTRACT

A memory device includes a substrate including a cell region and a peripheral region; a bottom electrode disposed on the substrate in the cell region, as a constituent element of a cell capacitor; a dummy electrode layer disposed on the substrate in the peripheral region; and a dummy bottom electrode disposed on the dummy electrode layer in the peripheral region, and disposed at a same level as the bottom electrode.

### CROSS-REFERENCE TO RELATED APPLICATION

The present application claims priority under 35 U.S.C. § 119(a) to Korean Patent Application No. 10-2024-0094727 filed on Jul. 18, 2024, which is incorporated herein by reference in its entirety.

### BACKGROUND

### 1. Technical Field

Embodiments of the present disclosure relate to a memory device, and more particularly, to a memory device including a bottom electrode, and a method of forming the same.

### 2. Related Art

Memory devices are attracting attention as important elements in the electronics industry due to their characteristics such as miniaturization, multifunctionality and/or low manufacturing cost. As the electronics industry has developed rapidly, memory devices are becoming increasingly highly integrated. In order for high integration of memory devices, the line width of wirings (i.e., metal lines) included in the memory devices is gradually decreasing and the size of memory cells is becoming smaller. Due to this fact, the difficulty of a process for forming the memory cells is increasing.

### SUMMARY

Various embodiments of the present disclosure are directed to providing a memory device capable of preventing deterioration of device characteristics due to a defect occurring in the fabrication process, and a method of forming the same.

In an embodiment of the present disclosure, a memory device may include a substrate including a cell region and a peripheral region; a bottom electrode disposed on the substrate in the cell region, as a constituent element of a cell capacitor; a dummy electrode layer disposed on the substrate in the peripheral region; and a dummy bottom electrode disposed on the dummy electrode layer in the peripheral region, and disposed at a same level as the bottom electrode.

In an embodiment of the present disclosure, a memory device may include a substrate including a cell region and a peripheral region; a bottom electrode disposed on the substrate in the cell region, as a constituent element of a cell capacitor; a dummy electrode layer disposed on the substrate in the peripheral region; a dummy bottom electrode disposed on the dummy electrode layer in the peripheral region, and disposed at a same level as the bottom electrode; an insulating layer surrounding the dummy bottom electrode; and a first interlayer insulating layer disposed on the insulating layer.

An embodiment of the present disclosure provides a method of forming a memory device, the method comprising forming a structure including transistors and an isolation insulating layer on a substrate including a cell region and a peripheral region; forming a landing pad in cell region while forming a dummy electrode layer and a wiring in the peripheral region; and forming a bottom electrode disposed on the landing pad in the cell region, as a constituent element of a cell capacitor, while forming a dummy bottom electrode on the dummy electrode layer in the peripheral region.

According to the embodiments of the present disclosure, it is possible to prevent device characteristics of memory cells from deteriorating due to a defect occurring in the fabrication process.

### BRIEF DESCRIPTION OF THE DRAWINGS

FIG. 1 is a plan view illustrating a memory device according to an embodiment of the present disclosure.

FIG. 2 is a view illustrating a cross-sectional structure of the memory device according to an embodiment of the present disclosure.

FIGS. 3 and 4 are views illustrating other cross-sectional structures of the memory device according to embodiments of the present disclosure.

FIGS. 5 to 15 are views illustrating a method for forming a memory device according to an embodiment of the present disclosure.

FIGS. 16 to 18 are views illustrating another method for forming a memory device according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Embodiments in accordance with the concepts may be carried out in various forms, and the scope of the present disclosure is not limited to the embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

In the accompanying drawings, two directions that are parallel to the upper surface of a substrate are defined as a first direction FD and a second direction SD, respectively, and a direction that vertically protrudes from the upper surface of the substrate is defined as a third direction VD. The first direction FD and the second direction SD may be substantially perpendicular to each other. The third direction VD is a direction that is perpendicular to the first direction FD and the second direction SD. In the following description, the term ‘vertical’ or ‘vertical direction’ will be used as substantially the same meaning as the third direction VD. In the drawings, a direction indicated by an arrow and a direction opposite thereto represent the same direction. Further, for illustrative purpose, cross-sectional structures shown in the drawings may not represent a cross-section taken along a linear line.

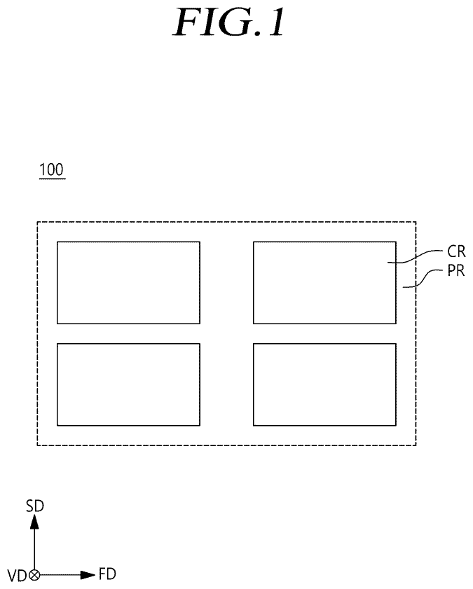

FIG. 1 is a plan view illustrating a memory device 100 according to an embodiment of the present disclosure.

Referring to FIG. 1, the memory device 100 includes a cell region (i.e., a core region) CR and a peripheral region PR. For the sake of convenience in description, only part of the cell region CR and part of the peripheral region PR are illustrated in FIG. 1. The cell region CR is a region where a plurality of memory cells are disposed. The peripheral region PR is a region where various circuits and elements for driving memory cells are disposed. The peripheral region PR is located outside the cell region CR. In FIG. 1, the cell region CR is depicted as a quadrangular shape, but this is an example and the shape of the cell region CR is not limited thereto.

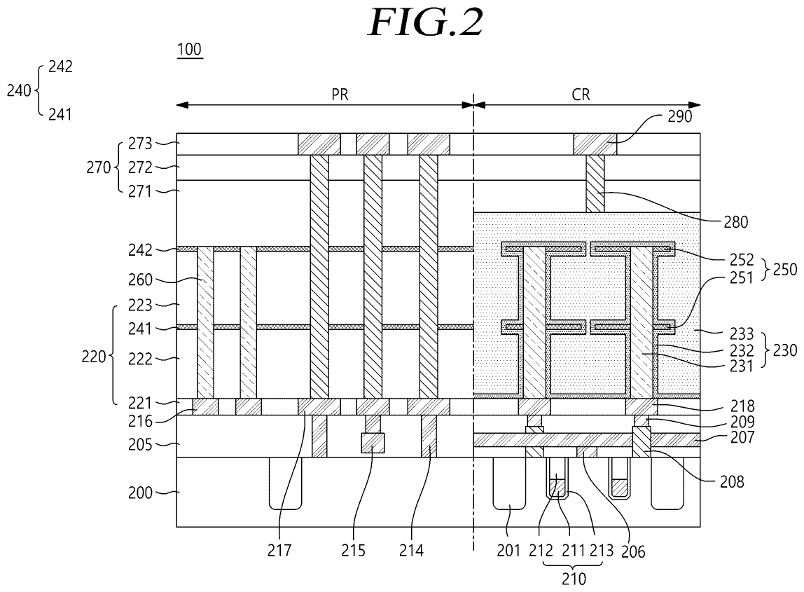

FIG. 2 is a view illustrating a cross-sectional structure of the memory device 100 according to an embodiment of the present disclosure.

Referring to FIG. 2, the memory device 100 includes a substrate 200, an isolation layer 201, a gate structure 210, an isolation insulating layer 205, a bit line contact 206, a bit line 207, a lower contact plug 208, an upper contact plug 209, a contact 214, a gate 215, an insulating layer 220, a dummy electrode layer 216, a wiring 217, a landing pad 218, a capacitor (i.e., a cell capacitor) 230, a support layer 240, a support pattern 250, a dummy bottom electrode 260, an interlayer insulating layer 270, a through contact 280, and a wiring electrode layer 290.

The substrate 200 may include a semiconductor substrate such as a silicon wafer or an SOI (silicon on insulator) wafer. The substrate 200 may include a III-V group semiconductor substrate, for example, a compound semiconductor substrate such as GaAs. The substrate 200 may include monocrystalline silicon, polysilicon, amorphous silicon, monocrystalline silicon germanium, polycrystalline silicon germanium, carbon-doped silicon, or a combination thereof.

The substrate 200 includes at least one isolation layer 201 in the cell region CR and the peripheral region PR. The isolation layer 201 may be formed using a trench isolation technology such as shallow trench isolation (STI). The isolation layer 201 may include silicon oxide, silicon nitride, silicon oxynitride, low-k dielectric, high-k dielectric or a combination thereof.

In the cell region CR, the gate structure 210 may be buried in the substrate 200. The gate structure 210 includes a word line 211, a gate capping layer 212 and a gate insulating layer 213. The upper surface of the word line 211 is located at a lower level than the upper surface of the substrate 200. The word line 211 may be a buried gate or a buried word line. The gate capping layer 212 is disposed on the word line 211. The gate insulating layer 213 surrounds the side surfaces of the word line 211 and the gate capping layer 212.

The word line 211 may include a conductive material such as metal, metal oxide, metal nitride, metal silicide, polysilicon, conductive carbon or a combination thereof. The gate capping layer 212 may include silicon oxide, silicon nitride, silicon oxynitride, low-k dielectric, high-k dielectric or a combination thereof. The gate insulating layer 213 may include silicon oxide, silicon nitride, silicon oxynitride, high-k dielectric or a combination thereof.

The isolation insulating layer 205, the bit line contact 206, the contact plugs 208 and 209 and the contact 214 are disposed on the substrate 200.

In the cell region CR, the bit line 207 is disposed on the bit line contact 206. The bit line 207 may be arranged in a direction perpendicular to the word line 211. For example, when the bit line 207 is arranged in the first direction FD, the word line 211 may be arranged in the second direction SD. The bit line 207 might not contact the contact plugs 208 and 209. That is, although not illustrated, an insulating layer may be disposed between the bit line 207 and the contact plugs 208 and 209. Landing pads 218 and a first insulating layer 221 are disposed on upper contact plugs 209. The landing pads 218 overlap the upper contact plugs 209 in the vertical direction VD.

In the peripheral region PR, contacts 214 and the gate 215 are disposed on the substrate 200. Wirings 217 and the first insulating layer 221 are disposed on the contacts 214. The wirings 217 overlap the contacts 214 in the vertical direction VD. In an embodiment, the contacts 214 and the gate 215 may be source and drain electrodes and a gate electrode of a transistor which constitutes each of various circuits are located in the peripheral region PR.

In the peripheral region PR, the dummy electrode layer 216 is disposed on the isolation insulating layer 205. The number of dummy electrode layers 216 may be one or more. The dummy electrode layers 216 may be disposed spaced apart from each other. The dummy electrode layer 216 is disposed at the same layer (i.e., at the same level or on the same latitude) as the wirings 217 or the landing pads 218. In FIG. 2, the dummy electrode layer 216 is depicted as being disposed farther away from the cell region CR than the wirings 217, but is not limited thereto. For example, the dummy electrode layer 216 may be disposed closer to the cell region CR than the wirings 217.

The bit line contact 206, the bit line 207, the contact plugs 208 and 209, the landing pad 218, the contact 214, the gate 215, the wiring 217 and the dummy electrode layer 216 may include a conductive material such as metal, metal oxide, metal nitride, metal silicide, polysilicon, conductive carbon or a combination thereof.

In the cell region CR, a bottom electrode 231, a dielectric layer 232, a top electrode 233 and the support pattern 250 are disposed on the first insulating layer 221 and the landing pad 218. The bottom electrode 231, the dielectric layer 232 and the top electrode 233 constitute the capacitor 230 of a memory cell. Although not illustrated, an etch stop layer may be additionally disposed between the first insulating layer 221 and the dielectric layer 322.

The bottom electrode 231 overlaps the landing pad 218 in the vertical direction VD. The support pattern 250 is disposed on the sidewall of the bottom electrode 231. The support pattern 250 surrounds the side surface of the bottom electrode 231. The support pattern 250 includes a first support pattern 251 and a second support pattern 252 over the first support pattern 251. A support pattern 250 which is disposed on the sidewall of one bottom electrode 231 may be separated from a support pattern 250 which is disposed on the sidewall of another bottom electrode 231.

The dielectric layer 232 is disposed to cover the surfaces of the bottom electrode 231 and the support pattern 250. The top electrode 233 is disposed on the dielectric layer 232. The upper surface of the top electrode 233 may be located at a higher level than the upper surface of the bottom electrode 231.

The bottom electrode 231 and the top electrode 233 may include a conductive material such as metal, metal oxide, metal nitride, metal silicide, polysilicon, conductive carbon or a combination thereof. The support pattern 250 may include silicon nitride or silicon carbonitride, but is not limited thereto. The dielectric layer 232 may include high-k dielectric, silicon oxide, silicon nitride or a combination thereof.

In the peripheral region PR, on the dummy electrode layer 216, the first insulating layer 221 and the wiring 217, there are disposed a second insulating layer 222, a third insulating layer 223, the support layer 240, the dummy bottom electrode 260 and the through contact 280.

A first support layer 241 is disposed on the second insulating layer 222. The third insulating layer 223 is disposed on the first support layer 241. A second support layer 242 is disposed on the third insulating layer 223. The first support layer 241 and the second support layer 242 are disposed on the side surface of the dummy bottom electrode 260, and surround the side surface of the dummy bottom electrode 260. The first support layer 241 and the second support layer 242 are disposed at the same layers (i.e., at the same levels or on the same latitudes) as the first support pattern 251 and the second support pattern 252, respectively. The first support layer 241 and the second support layer 242 are disposed spaced apart in a direction perpendicular to the upper surface of the substrate 200. That is, the first support layer 241 and the second support layer 242 are disposed on a different latitude. In an embodiment, the first support pattern 251 and the second support pattern 252 may be formed by etching parts of the first support layer 241 and the second support layer 242, respectively.

The first support layer 241 and the second support layer 242 may include silicon nitride or silicon carbonitride. The first support pattern 251 may include the same material as a material that forms the first support layer 241, and the second support pattern 252 may include the same material as a material that forms the second support layer 242. The insulating layers 221, 222 and 223 may include oxide (e.g., silicon dioxide).

The dummy bottom electrode 260 is disposed on the dummy electrode layer 216. Each dummy bottom electrode 260 corresponds to one dummy electrode layer 216. The number of dummy bottom electrodes 260 may be one or more. In an embodiment, the number of dummy bottom electrodes 260 may be the same as the number of dummy electrode layers 216. The dummy bottom electrode 260 contacts the dummy electrode layer 216 by passing through the second support layer 242, the third insulating layer 223, the first support layer 241 and the second insulating layer 222.

In an embodiment, as the dummy electrode layer 216 is disposed under the dummy bottom electrode 260, the dummy bottom electrode 260 may be stably fixed, and accordingly, a leaning phenomenon of the dummy bottom electrode 260 may be prevented.

In an embodiment, the dummy bottom electrode 260 may be formed by the same process as a process by which the bottom electrode 231 is formed. The dummy bottom electrode 260 may be disposed at the same layer (i.e., at the same level or on the same latitude) as the bottom electrode 231, and may be formed of the same material as the bottom electrode 231. In addition, the length in the vertical direction VD of the dummy bottom electrode 260 may be the same as the length in the vertical direction VD of the bottom electrode 231.

The interlayer insulating layer 270 and the wiring electrode layer 290 are disposed on the top electrode 233 of the cell region CR and the second support layer 242 of the peripheral region PR.

The interlayer insulating layer 270 includes a first interlayer insulating layer 271, a second interlayer insulating layer 272 and a third interlayer insulating layer 273. The lower surface of the first interlayer insulating layer 271 contacts the upper surface of the second support layer 242. The second interlayer insulating layer 272 is disposed on the first interlayer insulating layer 271. The third interlayer insulating layer 273 is disposed on the second interlayer insulating layer 272. Each of the interlayer insulating layers 271, 272 and 273 may include oxide, but is not limited thereto.

In an embodiment, the lowermost surface of the first interlayer insulating layer 271, that is, the lower surface of a section of the first interlayer insulating layer 271 which is located in the peripheral region PR, may be located at the same level as the upper surface of the bottom electrode 231 or at a level higher than the upper surface of the bottom electrode 231.

In an embodiment, the upper surface of the first interlayer insulating layer 271 in the peripheral region PR may be located at the same level as the upper surface of the first interlayer insulating layer 271 in the cell region CR. Namely, the first interlayer insulating layer 271 may have a flat upper surface.

In an embodiment, the thickness of the first interlayer insulating layer 271 may be equal to or greater than 1000 Å and equal to or less than 5000 Å in the peripheral region PR. When the thickness of the first interlayer insulating layer 271 is less than 1000 Å, the thickness of the first interlayer insulating layer 271 disposed in the cell region CR is thin, and thus, an insulating function between the top electrode 233 and the wiring electrode layer 290 is not properly performed. In addition, because the thickness difference between the section of the first interlayer insulating layer 271 disposed in the peripheral region PR and a section of the first interlayer insulating layer 271 disposed in the cell region CR is reduced due to the dummy bottom electrode 260 and the insulating layers 222 and 223 disposed in the peripheral region PR, the thickness of the first interlayer insulating layer 271 might be set not to be greater than 5000 Å, in the peripheral region PR.

Through contacts 280 contact layers disposed thereunder by passing through the second interlayer insulating layer 272 and the first interlayer insulating layer 271. In the cell region CR, the through contact 280 contacts the top electrode 233 by passing through the second interlayer insulating layer 272 and the first interlayer insulating layer 271. In the peripheral region PR, the through contact 280 contacts a corresponding wiring 217 by passing through the second interlayer insulating layer 272, the first interlayer insulating layer 271, the support layer 240, the third insulating layer 223 and the second insulating layer 222.

The wiring electrode layer 290 is disposed on the through contact 280. Each wiring electrode layer 290 corresponds to one through contact 280. The lower surface of the wiring electrode layer 290 contacts the upper surface of the through contact 280.

The through contact 280 and the wiring electrode layer 290 may include a conductive material such as metal, metal oxide, metal nitride, metal silicide, polysilicon, conductive carbon or a combination thereof.

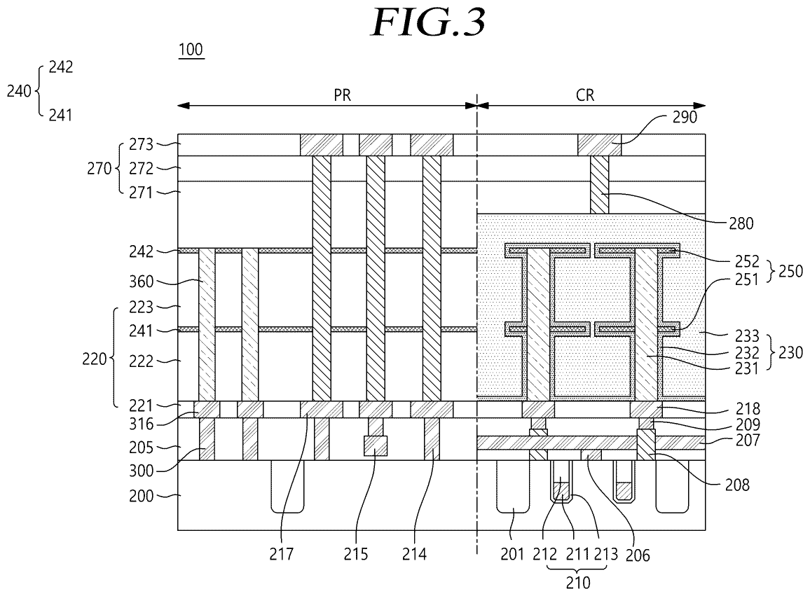

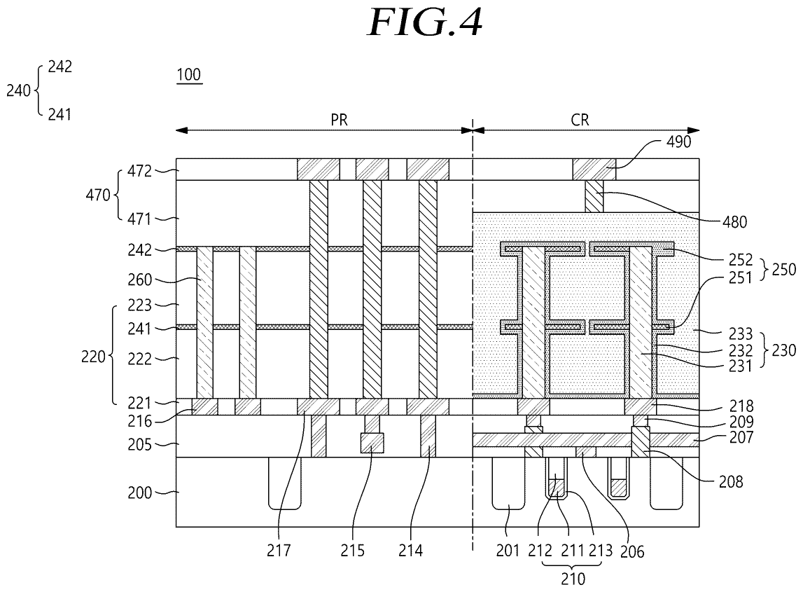

FIGS. 3 and 4 are views illustrating other cross-sectional structures of the memory device according to embodiments of the present disclosure.

Referring to FIG. 3, the memory device 100 includes a substrate 200, an isolation layer 201, a gate structure 210, an isolation insulating layer 205, a bit line contact 206, a bit line 207, a lower contact plug 208, an upper contact plug 209, a contact 214, a gate 215, an insulating layer 220, a dummy electrode layer 316, a wiring 217, a landing pad 218, a capacitor (i.e., a cell capacitor) 230, a support layer 240, a support pattern 250, a dummy bottom electrode 360, an interlayer insulating layer 270, a through contact 280, a wiring electrode layer 290, and a dummy contact 300.

In a peripheral region PR, the dummy contact 300 is disposed under the dummy electrode layer 316. The dummy contact 300 may contact the lower surface of the dummy electrode layer 316, and may pass through the isolation insulating layer 205. The number of dummy contacts 300 may be one or more. In an embodiment, the number of dummy contacts 300 may be the same as the number of dummy electrode layers 316.

Each dummy contact 300 corresponds to one dummy electrode layer 316. Each dummy electrode layer 316 corresponds to one dummy bottom electrode 360. Each dummy contact 300 corresponds to one dummy bottom electrode 360 and is disposed below one dummy bottom electrode 360.

In an embodiment, as each dummy contacts 300 corresponds to one dummy bottom electrode 360 and is disposed below one dummy bottom electrode 360, the dummy bottom electrode 360 disposed in the peripheral region PR may be more stably fixed. Therefore, the leaning phenomenon of the dummy bottom electrode 360 may be effectively prevented.

Referring to FIG. 4, the memory device 100 includes a substrate 200, an isolation layer 201, a gate structure 210, an isolation insulating layer 205, a bit line contact 206, a bit line 207, a lower contact plug 208, an upper contact plug 209, a contact 214, a gate 215, an insulating layer 220, a dummy electrode layer 216, a wiring 217, a landing pad 218, a capacitor (i.e., a cell capacitor) 230, a support layer 240, a support pattern 250, a dummy bottom electrode 260, an interlayer insulating layer 470, a through contact 480, and a wiring electrode layer 490.

The interlayer insulating layer 470 includes a first interlayer insulating layer 471 and a second interlayer insulating layer 472. The first interlayer insulating layer 471 is disposed on a top electrode 233 and a second support layer 242. The second interlayer insulating layer 472 is disposed on the first interlayer insulating layer 471. The first interlayer insulating layer 471 and the second interlayer insulating layer 472 may include oxide.

Through contacts 280 contact layers disposed thereunder by passing through the first interlayer insulating layer 271. In a cell region CR, the through contact 480 contacts the top electrode 233 by passing through the first interlayer insulating layer 471. In a peripheral region PR, the through contact 480 contacts a corresponding wiring 217 by passing through the first interlayer insulating layer 471, the support layer 240, a third insulating layer 223 and a second insulating layer 222.

The wiring electrode layer 490 is disposed on the through contact 480. Each wiring electrode layer 490 corresponds to one through contact 480. The lower surface of the wiring electrode layer 490 contacts the upper surface of the through contact 480.

The through contact 480 and the wiring electrode layer 490 may include a conductive material such as metal, metal oxide, metal nitride, metal silicide, polysilicon, conductive carbon or a combination thereof.

In an embodiment, one interlayer insulating layer may be disposed between the wiring electrode layer 490 and the top electrode 233 or between the wiring electrode layer 490 and the second support layer 242. Because the thickness difference between a section of the first interlayer insulating layer 471 disposed in the peripheral region PR and a section of the first interlayer insulating layer 471 disposed in the cell region CR is reduced due to the dummy bottom electrode 260 disposed in the peripheral region PR, an interlayer insulating layer might not be additionally disposed on the first interlayer insulating layer 471 for planarization.

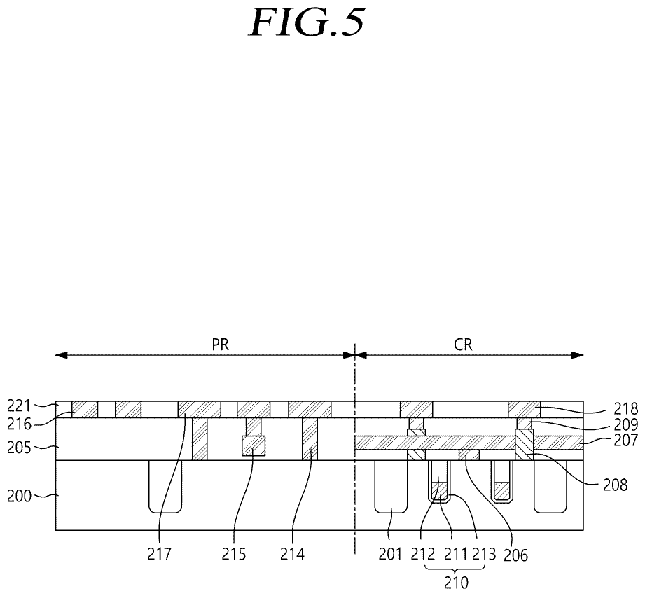

FIGS. 5 to 15 are views illustrating a method for forming a memory device according to an embodiment of the present disclosure.

Referring to FIG. 5, an isolation layer 201 and a gate structure 210 are formed in a substrate 200. An isolation insulating layer 205, a bit line contact 206, a bit line 207, a lower contact plug 208, an upper contact plug 209, a contact 214 and a gate 215 are formed on the substrate 200. A dummy electrode layer 216, a wiring 217 and a landing pad 218 are formed on the isolation insulating layer 205, the contact 214 and the upper contact plug 209, respectively.

The dummy electrode layer 216 is formed in a first insulating layer 221 in a peripheral region PR. The dummy electrode layer 216 may be disposed at the same layer (i.e., at the same level or on the same latitude) as the landing pad 218. The dummy electrode layer 216 may be located farther away from a cell region CR than the wiring 217, but is not limited thereto. The dummy electrode layer 216 may be located closer to the cell region CR than the wiring 217. The number of dummy electrode layers 216 may be one or more.

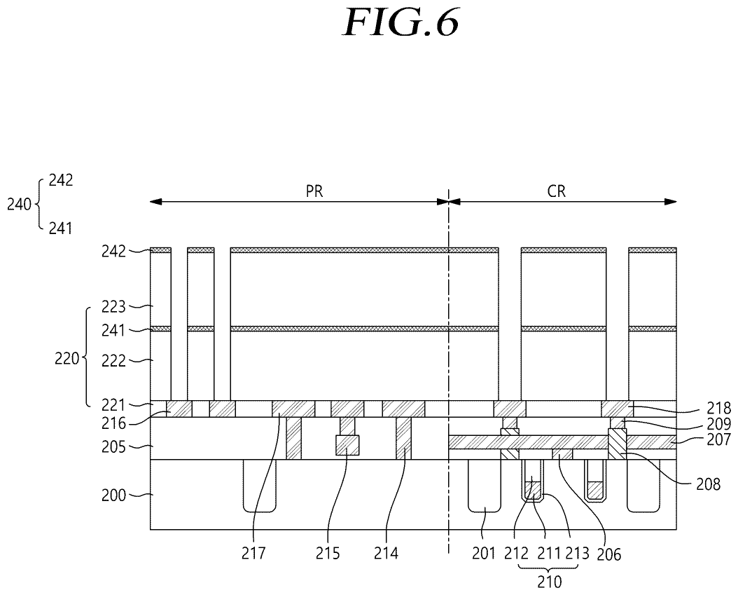

Referring to FIG. 6, a second insulating layer 222 is formed on the dummy electrode layer 216, the wiring 217, the landing pad 218 and the first insulating layer 221. A first support layer 241 is formed on the second insulating layer 222. A third insulating layer 223 is formed on the first support layer 241. A second support layer 242 is formed on the third insulating layer 223.

Through holes which pass through the second support layer 242, the third insulating layer 223, the first support layer 241 and the second insulating layer 222 are formed in the cell region CR and the peripheral region PR. The through holes may be formed through anisotropic etching. The through hole formed in the cell region CR may expose the upper surface of the landing pad 218. The through hole formed in the peripheral region PR may expose the upper surface of the dummy electrode layer 216. In an embodiment, the vertical lengths of the through hole formed in the cell region CR and the through hole formed in the peripheral region PR may be the same. In an embodiment, the diameters of the through holes formed in the cell region CR and the through hole formed in the peripheral region PR may be the same.

Each through hole formed in the peripheral region PR corresponds to one dummy electrode layer 216. That is, the number of through holes formed in the peripheral region PR may be the same as the number of dummy electrode layers 216.

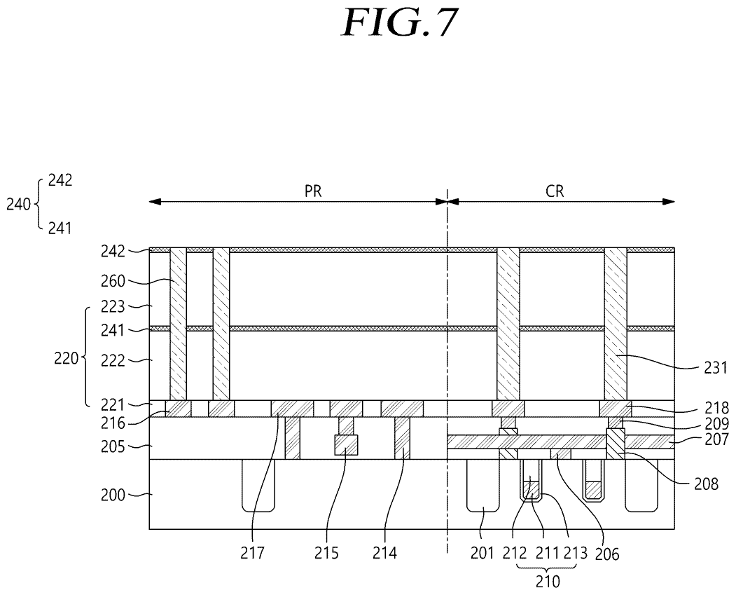

Referring to FIG. 7, in the cell region CR, a bottom electrode 231 is disposed to fill the through hole which is formed in the cell region CR. In the peripheral region PR, a dummy bottom electrode 260 is disposed to fill the through hole which is formed in the peripheral region PR. The lower surface of the dummy bottom electrode 260 contacts the upper surface of the dummy electrode layer 216. In an embodiment, the dummy bottom electrode 260 and the bottom electrode 231 may be formed of the same material.

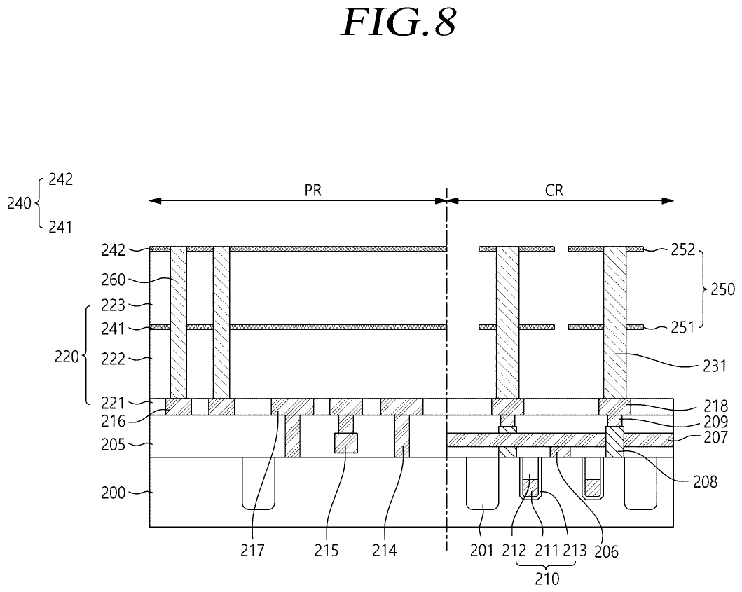

Referring to FIG. 8, parts of the first support layer 241 and the second support layer 242 may be opened in the cell region CR. As parts of the first support layer 241 and the second support layer 242 are opened, the remaining first support layer 241 and second support layer 242 form a first support pattern 251 and a second support pattern 252, respectively. Each of the first support pattern 251 and the second support pattern 252 surrounds the side surface of the bottom electrode 231. After the first support pattern 251 and the second support pattern 252 are formed, the second insulating layer 222 and the third insulating layer 223 are removed in the cell region CR.

The second insulating layer 222 and the third insulating layer 223 may be removed by a dip-out process. In an embodiment, the dip-out process may be a wet etching process.

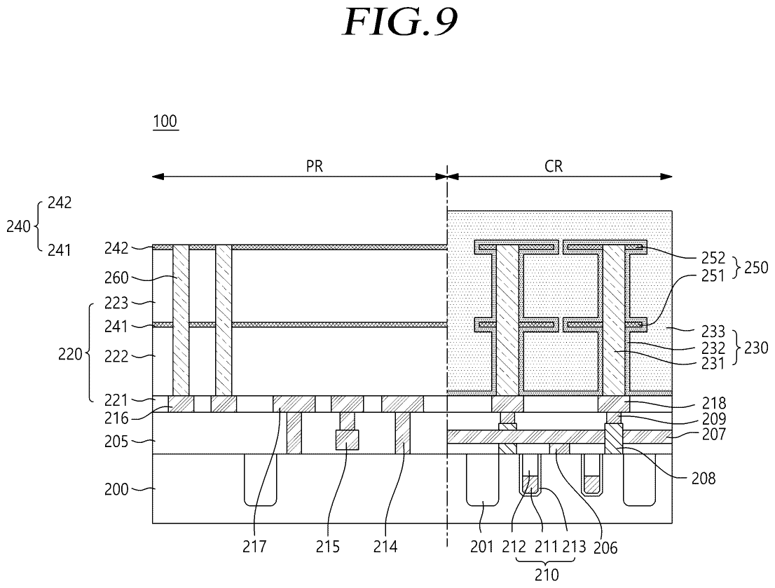

Referring to FIG. 9, in the cell region CR, a dielectric layer 232 is formed on the first insulating layer 221, the bottom electrode 231 and a support pattern 250. The dielectric layer 232 may be formed along the profiles of the bottom electrode 231 and the support pattern 250.

A top electrode 233 is formed on the dielectric layer 232. The top electrode 233 might not be formed in the peripheral region PR. However, the embodiment of the present disclosure is not limited thereto, and a part of the top electrode 233 may be disposed in the peripheral region PR. The upper surface of the top electrode 233 may be located at a higher level than the upper surfaces of the bottom electrode 231, the second support pattern 252 and the second support layer 242.

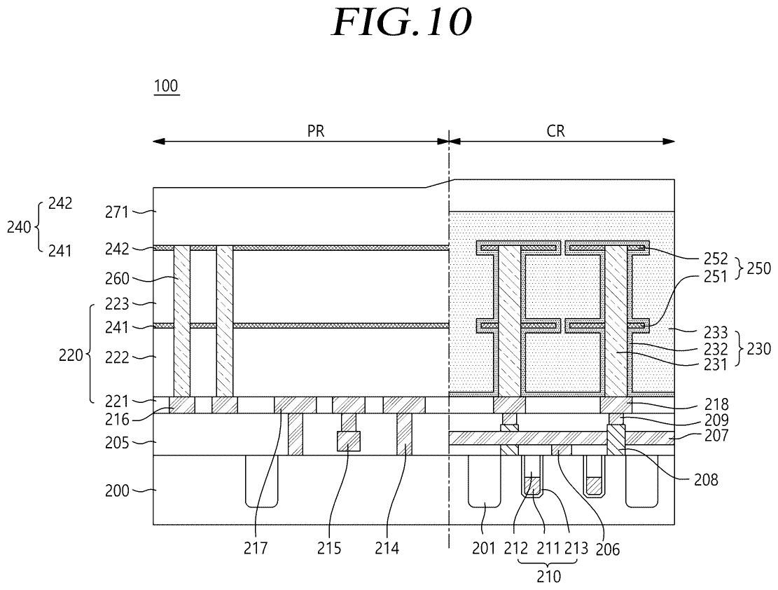

Referring to FIG. 10, a first interlayer insulating layer 271 is formed on the second support layer 242 and the top electrode 233. The upper surface of the first interlayer insulating layer 271 in the peripheral region PR may be located at a lower level than the upper surface of the first interlayer insulating layer 271 in the cell region CR. The first interlayer insulating layer 271 may have a step near the boundary between the cell region CR and the peripheral region PR.

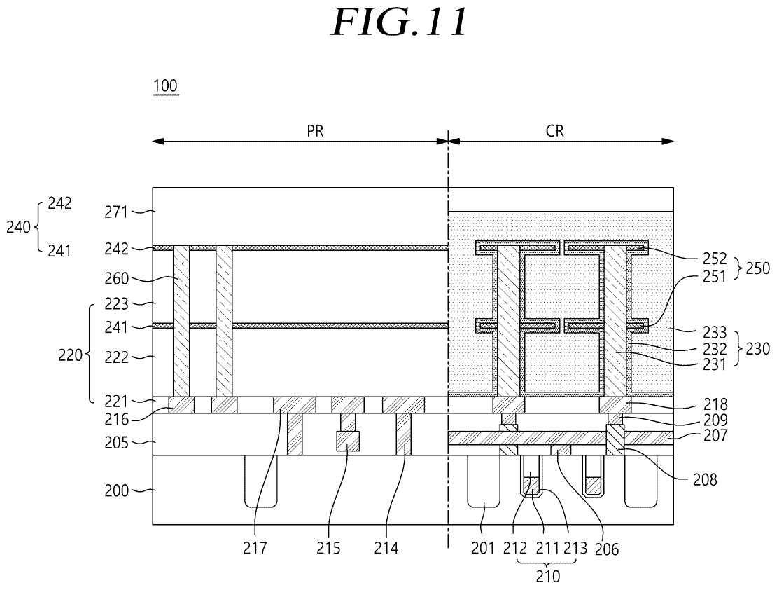

Referring to FIG. 11, in the cell region CR, the upper surface of the first interlayer insulating layer 271 may be partially removed by a chemical mechanical polishing (CMP) process. In an embodiment, the CMP process may proceed until the upper surface of the first interlayer insulating layer 271 in the cell region CR is located at the same level as the upper surface of the first interlayer insulating layer 271 in the peripheral region PR. In the peripheral region PR, the thickness of the first interlayer insulating layer 271 which remains after being removed by the CMP process may be equal to or greater than 1000 Å and equal to or less than 5000 Å.

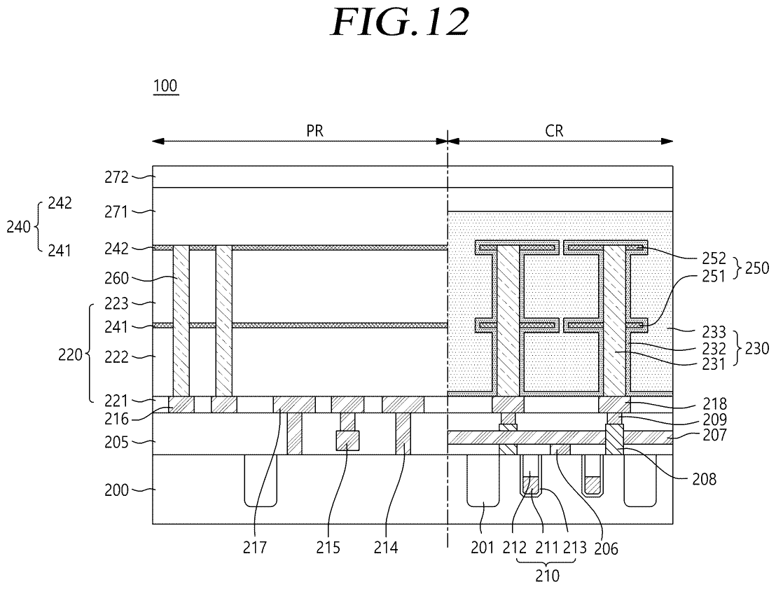

Referring to FIG. 12, a second interlayer insulating layer 272 is formed on the first interlayer insulating layer 271. In an embodiment, the second interlayer insulating layer 272 may be formed of a different material from the first interlayer insulating layer 271.

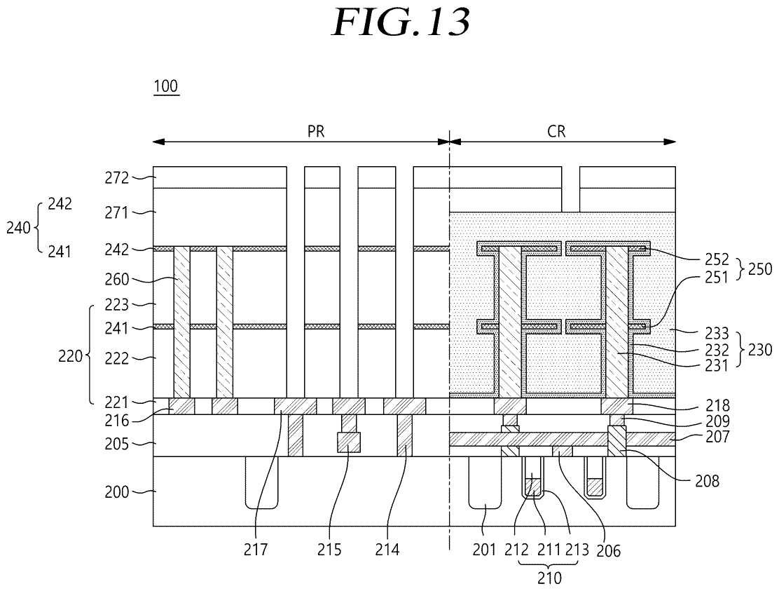

Referring to FIG. 13, in the peripheral region PR, through holes which pass through the second interlayer insulating layer 272, the first interlayer insulating layer 271, the second support layer 242, the third insulating layer 223, the first support layer 241 and the second insulating layer 222 are formed. In the cell region CR, a through hole which passes through the second interlayer insulating layer 272 and the first interlayer insulating layer 271 is formed. The through holes may be formed through anisotropic etching. The through holes formed in the peripheral region PR may expose the upper surfaces of wirings 217. The through hole formed in the cell region CR may expose the upper surface of the top electrode 233.

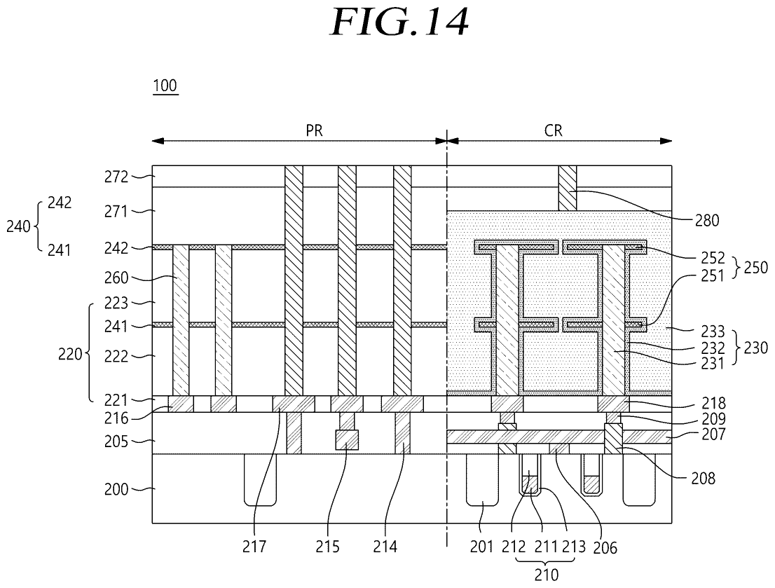

Referring to FIG. 14, in the cell region CR and the peripheral region PR, through contacts 280 are disposed to fill the through holes. In the peripheral region PR, the lower surface of the through contact 280 contacts the upper surface of the wiring 217. In the cell region CR, the lower surface of the through contact 280 contacts the upper surface of the top electrode 233.

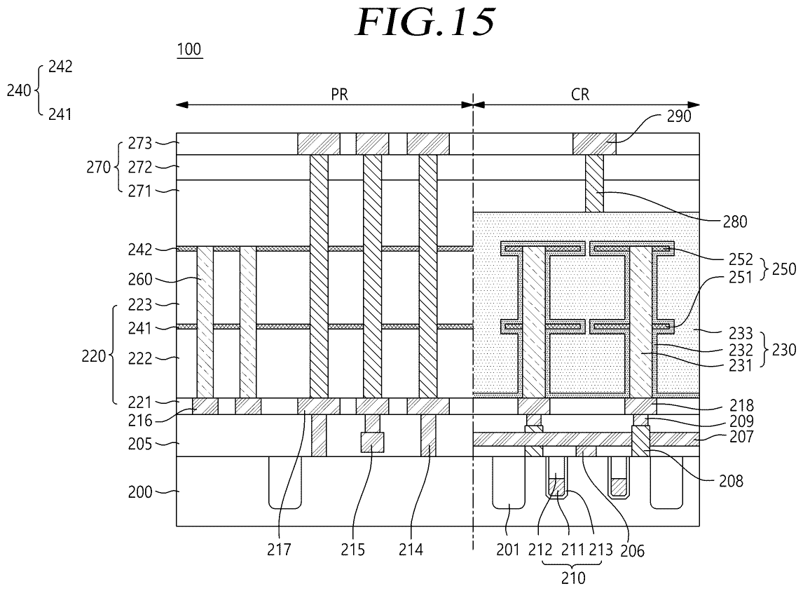

Referring to FIG. 15, a third interlayer insulating layer 273 is formed on the second interlayer insulating layer 272 and the through contacts 280. A wiring electrode layer 290 is formed in the third interlayer insulating layer 273. The wiring electrode layer 290 is formed on the through contact 280. Each wiring electrode layer 290 corresponds to one through contact 280.

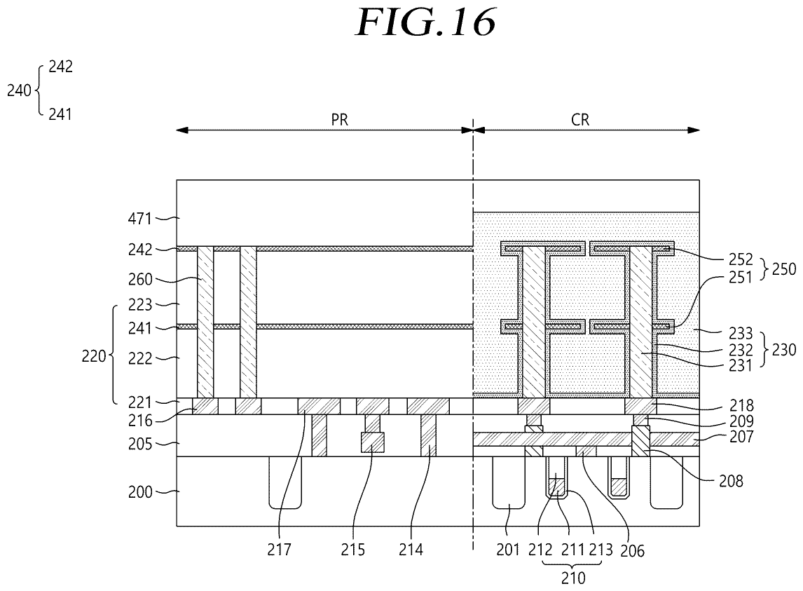

FIGS. 16 to 18 are views illustrating another method for forming a memory device according to an embodiment of the present disclosure.

The memory device illustrated in FIG. 16 may be formed by the same method as the method for manufacturing a memory device described above with reference to FIGS. 5 to 11. A first interlayer insulating layer 471 may be formed in the same manner as the first interlayer insulating layer 271 illustrated in FIG. 11.

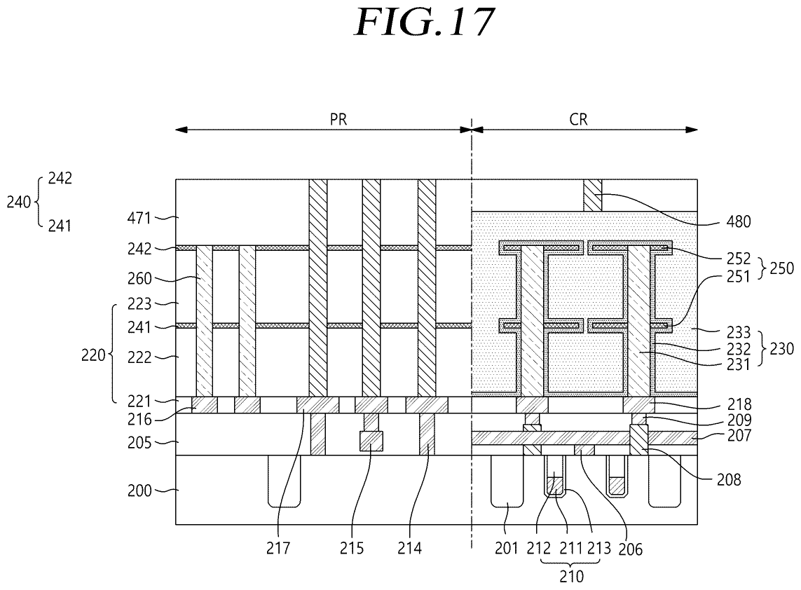

Referring to FIG. 17, in the peripheral region PR, through holes which pass through the first interlayer insulating layer 471, the second support layer 242, the third insulating layer 223, the first support layer 241 and the second insulating layer 222 are formed. In the cell region CR, a through hole which passes through the first interlayer insulating layer 471 is formed. In the cell region CR and the peripheral region PR, through contacts 480 are disposed to fill the through holes.

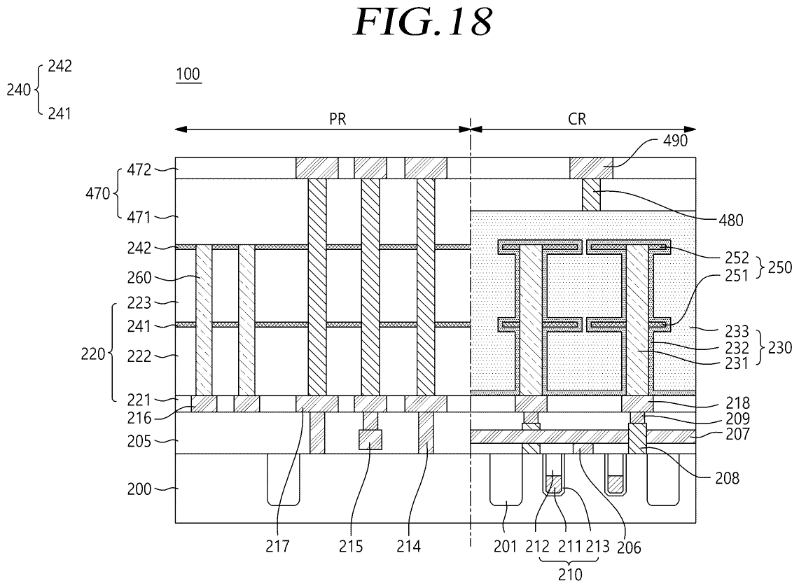

Referring to FIG. 18, a second interlayer insulating layer 472 is formed on the first interlayer insulating layer 471 and the through contacts 480. A wiring electrode layer 490 is formed in the second interlayer insulating layer 472. The wiring electrode layer 490 is formed on the through contact 480. Each wiring electrode layer 490 corresponds to one through contact 480.

Referring again to FIG. 2, in the peripheral region PR, the dummy electrode layer 216 is disposed in the first insulating layer 221. The dummy bottom electrode 260 is disposed on the dummy electrode layer 216. Each dummy bottom electrode 260 corresponds to one dummy electrode layer 216. The dummy bottom electrode 260 is formed through the same process as the bottom electrodes 231 disposed in the cell region CR. The height of the dummy bottom electrode 260 may be the same as the height of the bottom electrode 231.

According to the embodiments of the present disclosure, as the dummy bottom electrode 260 is disposed in the peripheral region PR, when the first interlayer insulating layer 271 is formed, the step of the first interlayer insulating layer 271 at the boundary between the peripheral region PR and the cell region CR may be formed to be small.

When the step of the first interlayer insulating layer 271 at the boundary between the peripheral region PR and the cell region CR is large, a CMP process should be performed relatively more to planarize the first interlayer insulating layer 271. Therefore, more residue may be generated during the CMP process. In addition, when the CMP process is excessively performed, a scratch may occur in the first interlayer insulating layer 271. When there is a region where residue from the CMP process accumulates or a region where a scratch occurs, a void may occur around the region during a subsequent process. As a bridge is formed between through holes by the void and a metal material is filled in a bridge region when subsequently forming the through contacts 280 by filling the metal material in the through holes, a problem may arise in that the through contacts 280 are likely to be connected to each other.

However, when the dummy bottom electrode 260 is disposed in the peripheral region PR to reduce the step of the first interlayer insulating layer 271 formed at the boundary between the peripheral region PR and the cell region CR, the CMP process may be performed relatively less, and accordingly, the occurrence of residue or a scratch during the CMP process may be reduced. Therefore, by preventing a void from occurring in a subsequent process, it is possible to prevent the formation of a bridge which connects through holes.

Hence, according to the embodiments of the present disclosure, it is possible to prevent a defect occurring in the fabrication process that may be generated within the peripheral region PR, and to prevent deterioration of the device characteristics of memory cells due to the defect occurring in the fabrication process.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A memory device comprising:
a substrate including a cell region and a peripheral region;
a bottom electrode disposed on the substrate in the cell region, as a constituent element of a cell capacitor;
a dummy electrode layer disposed on the substrate in the peripheral region; and
a dummy bottom electrode disposed on the dummy electrode layer in the peripheral region, and disposed at a same level as the bottom electrode.

2. The memory device according to claim 1, further comprising a landing pad disposed on the substrate in the cell region, and disposed at a same level as the dummy electrode layer.

3. The memory device according to claim 2, wherein the dummy bottom electrode includes a same material as a material which forms the bottom electrode.

4. The memory device according to claim 1, further comprising:
support layers disposed to surround the dummy bottom electrode, at different levels.

5. The memory device according to claim 1, further comprising:
a first interlayer insulating layer disposed on the dummy bottom electrode,
wherein the thickness of the first interlayer insulating layer is equal to or greater than about 1000 Å and equal to or less than about 5000 Å, in the peripheral region.

6. The memory device according to claim 5, wherein a lowermost surface of the first interlayer insulating layer is located at a level equal to or higher than an upper surface of the bottom electrode.

7. The memory device according to claim 5, further comprising:
a second interlayer insulating layer disposed on the first interlayer insulating layer;
a wiring electrode layer disposed on the second interlayer insulating layer; and
a through contact contacting a lower surface of the wiring electrode layer, and passing through the first interlayer insulating layer and the second interlayer insulating layer.

8. The memory device according to claim 5, further comprising:
a wiring electrode layer disposed on the first interlayer insulating layer; and
a through contact contacting a lower surface of the wiring electrode layer and passing through the first interlayer insulating layer.

9. The memory device according to claim 1, further comprising:
an isolation insulating layer disposed between the dummy electrode layer and the substrate, in the peripheral region; and
a dummy contact contacting a lower surface of the dummy electrode layer, and passing through the isolation insulating layer.

10. A memory device comprising:
a substrate including a cell region and a peripheral region;
a bottom electrode disposed on the substrate in the cell region, as a constituent element of a cell capacitor;
a dummy electrode layer disposed on the substrate in the peripheral region;
a dummy bottom electrode disposed on the dummy electrode layer in the peripheral region, and disposed at a same level as the bottom electrode;
an insulating layer surrounding the dummy bottom electrode; and
a first interlayer insulating layer disposed on the insulating layer.

11. The memory device according to claim 10, further comprising:
support layers surrounding the dummy bottom electrode.

12. The memory device according to claim 11, wherein:
the support layers comprise a first support layer and a second support layer located over the first support layer; and
the second support layer is located between the insulating layer and the first interlayer insulating layer.

13. The memory device according to claim 12, wherein an upper surface of the second support layer contacts a lower surface of the first interlayer insulating layer.

14. The memory device according to claim 10, wherein the thickness of the first interlayer insulating layer is equal to or greater than about 1000 Å and equal to or less than about 5000 Å, in the peripheral region.

15. The memory device according to claim 10, wherein a lowermost surface of the first interlayer insulating layer is located at a level equal to or higher than an upper surface of the bottom electrode.

16. The memory device according to claim 10, further comprising:
a second interlayer insulating layer disposed on the first interlayer insulating layer;
a wiring electrode layer disposed on the second interlayer insulating layer; and
a through contact contacting a lower surface of the wiring electrode layer, and passing through the first interlayer insulating layer and the second interlayer insulating layer.

17. The memory device according to claim 10, further comprising:
a wiring electrode layer disposed on the first interlayer insulating layer; and
a through contact contacting a lower surface of the wiring electrode layer, and passing through the first interlayer insulating layer.

18. The memory device according to claim 10, further comprising:
an isolation insulating layer disposed between the dummy electrode layer and the substrate, in the peripheral region; and
a dummy contact contacting a lower surface of the dummy electrode layer, and passing through the isolation insulating layer.

19. A method of forming a memory device, the method comprising:
forming a structure including transistors and an isolation insulating layer on a substrate including a cell region and a peripheral region;
forming a landing pad in cell region while forming a dummy electrode layer and a wiring in the peripheral region; and
forming a bottom electrode disposed on the landing pad in the cell region, as a constituent element of a cell capacitor, while forming a dummy bottom electrode on the dummy electrode layer in the peripheral region.

20. The method according to claim 19, wherein:
the dummy electrode layer and the landing pad are formed to have a same level; and
the dummy bottom electrode and the bottom electrode are formed to have a same level.
